(19) United States
(12) Patent Application Publication
(10) Pub. No.: US 2024/0032331 A1
(43) Pub. Date: Jan. 25, 2024

(54) DISPLAY PANEL AND METHOD OF MANUFACTURING DISPLAY PANEL AND MACHINE OF MANUFACTURING DISPLAY PANEL

(71) Applicant: Shenzhen China Star Optelectronics Semiconductor Display Technology Co., Ltd., Shenzhen, Guangdong (CN)

(72) Inventors: Zhijun Wan, Shenzhen, Guangdong (CN); Feng Wei, Shenzhen, Guangdong (CN); Jinchuan Li, Shenzhen, Guangdong (CN); Weiran Cao, Shenzhen, Guangdong (CN)

(73) Assignee: Shenzhen China Star Optoelectronics Semiconductor Display Technology Co. Ltd., Shenzhen, Guangdong (CN)

(21) Appl. No.: 17/622,812

(22) PCT Filed: Dec. 21, 2021
(86) PCT No.: PCT/CN2021/140173

§ 371 Date: Jun. 22, 2023

(30) Foreign Application Priority Data
Dec. 15, 2021 (CN) 202111534479.3

(51) Int. Cl. H10K 59/12; H10K 59/122; H10K 71/16

(52) U.S. Cl. CPC H10K 59/1201; H10K 59/122; H10K 71/166

(57) ABSTRACT

A display panel, a method of manufacturing a display panel, and a machine of manufacturing a display panel are provided. The display panel includes the plurality of stacked metal sub-layers and the first passivation sub-layer and the second passivation sub-layer stacked. The first passivation sub-layer is disposed between the metal layer and the second passivation layer. Material of the first passivation sub-layer includes silicon nitride. The first passivation sub-layer covers the untidy area at the ends of the molybdenum-titanium alloy thin layer to avoid from detachment of the passivation layer, and meanwhile to solve the issues of simplifying the manufacturing process of the display panel, and to avoid from oxidation of the bonding pads.

### FIELD

The present disclosure relates to display technologies, and more particularly, to a display panel, a method of manufacturing a display panel, and a machine of manufacturing a display panel.

### BACKGROUND

In recent years, inkjet printing (UP) process has potential to significantly reduce manufacturing costs, making organic light emitting diode (OLED) more cost-competitive in product applications including TVs and tablet computers. For OLED panels, in addition to the inkjet printing (IJP) process, an evaporation (EV) process or a sputtering (SPT) process is still required. Due to material limitations of inks of electron transport material (ETM) and electron injection material (EIM), at present, OLED panels use the UP process to deposit a hole injection layer (HIL), a hole transport layer (HTL), a light emitting layer (EML) and other OLED functional layers and use the EV/SPT process to deposit an electron transport layer (ETL), an electron injection layer (EIL), a cathode (CAT), and other OLED functional layers.

The CAT needs to be connected to a metal trace on the substrate to realize the driving circuit to control the OLED to emit light. One way is to lap the CAT film directly with the metal traces. Therefore, a size of a mask opening required for depositing CAT is different from a size of a mask opening required for depositing ETL and EIL to realize difference in film formation area to prevent the poorly conductive ETL and EIL films from covering the metal traces to affect lap connection between the CAT and the metal trace.

For an OLED panel evaporation production line, in terms of platform design, different cyclic processes are acquired according to different masks. Based on the above-mentioned design that the size of the mask opening required for depositing CAT is different from the size of the mask opening required for depositing ETL and EIL, the layout of the production line platform requires at least two circulation processes, and equipment investment cost is high.

Therefore, there is an urgent need to simultaneously solve the above-mentioned simplification of the display panel manufacturing process and overlap of the CAT film layer and the metal wiring.

### SUMMARY

In view of the above, the present disclosure provides a display panel, a method of manufacturing a display panel, and a machine of manufacturing a display panel to solve the technical issues of simplification of the display panel manufacturing process and overlap of the CAT film layer and the metal wiring.

In order to achieve above-mentioned object of the present disclosure, one embodiment of the disclosure provides a display panel, dividing to a display region and a bonding region and including:
a substrate;
a bonding pad pattern disposed on the substrate within the bonding region;
an anode disposed on the substrate within the display region;
a light emitting layer disposed on the anode;
an organic electronic functional layer covering the light emitting layer; and

a cathode covering the organic electronic functional layer, wherein the organic electronic functional layer further covers a part of the bonding pad pattern, and the cathode further covers another part of the bonding pad pattern.

In one embodiment of the display panel, the organic electronic functional layer includes an electron transport layer and an electron injection layer stacked thereon.

In one embodiment of the display panel, the organic electronic functional layer extends from the display region to the bonding region, and the cathode extends from the display region to the bonding region.

In one embodiment of the disclosure, the display panel further includes a driving circuit layer disposed on the substrate, a planarization layer covering the driving circuit layer, the anode disposed on the planarization layer, a pixel definition layer disposed on the planarization layer and covering part of the anode, wherein the pixel definition layer is provided with an opening, a hole injection layer and a hole transport layer are disposed in the opening in a stack, and the light emitting layer is disposed on the hole transport layer.

In one embodiment of the display panel, the organic electronic functional layer includes an electron transport layer covering the light emitting layer, the pixel definition layer, a part of the driving circuit layer and contacting with the bonding pad pattern and an electron injection layer covering the electron transport layer, contacting the bonding pad pattern, and covering a part of the bonding pad pattern, wherein the cathode covers the electron injection layer and another part of the bonding pad pattern.

Another embodiment of the disclosure further provides a method of manufacturing a display panel, including steps of:
providing a substrate, wherein the substrate is dividing to a display region and a bonding region, and the substrate includes a bonding pad pattern disposed within the bonding region and light emitting layer disposed within the display region;
depositing an organic electronic functional layer covering the light emitting layer and a part of the bonding pad pattern; and
depositing a cathode covering the organic electronic functional layer and another part of the bonding pad pattern.

In one embodiment of the method of manufacturing the display panel, the step of depositing the organic electronic functional layer covering the light emitting layer and the part of the bonding pad pattern and the step of depositing the cathode covering the organic electronic functional layer and another part of the bonding pad pattern use a same mask.

In one embodiment of the method of manufacturing the display panel, the step of depositing the organic electronic functional layer covering the light emitting layer and the part of the bonding pad pattern includes depositing the organic electronic functional layer by evaporation, wherein an overspray of the organic electronic functional layer covers the part of the bonding pad pattern.

In one embodiment of the method of manufacturing the display panel, the step of depositing the organic electronic functional layer covering the light emitting layer and the part of the bonding pad pattern further includes widening a distance between an evaporation source and the substrate to reduce the overspray of the organic electronic functional layer.

In one embodiment of the method of manufacturing the display panel, the step of depositing the organic electronic functional layer covering the light emitting layer and the part of the bonding pad pattern further includes changing an evaporation angle of an evaporation source to reduce the overspray of the organic electronic functional layer.

In one embodiment of the method of manufacturing the display panel, the step of depositing the cathode covering the organic electronic functional layer and another part of the bonding pad pattern includes depositing the cathode by evaporation, wherein an overspray of the cathode covers the overspray of the organic electronic functional layer and another part of the bonding pad pattern.

In one embodiment of the method of manufacturing the display panel, the step of depositing the cathode covering the organic electronic functional layer and another part of the bonding pad pattern further includes changing an evaporation angle of an evaporation source to increase the overspray of the cathode.

In one embodiment of the method of manufacturing the display panel, the step of depositing the cathode covering the organic electronic functional layer and another part of the bonding pad pattern further includes widening a distance between an evaporation source and the substrate to increase the overspray of the cathode.

In one embodiment of the method of manufacturing the display panel, the step of depositing the cathode covering the organic electronic functional layer and another part of the bonding pad pattern further includes widening a distance between a mask and the substrate to increase the overspray of the cathode.

In one embodiment of the method of manufacturing the display panel, the step of depositing the cathode covering the organic electronic functional layer and another part of the bonding pad pattern includes depositing the cathode by sputtering, wherein an overspray of the cathode covers the overspray of the organic electronic functional layer and another part of the bonding pad pattern.

In one embodiment of the method of manufacturing the display panel, the step of depositing the cathode covering the organic electronic functional layer and another part of the bonding pad pattern further includes widening a distance between a sputtering target and the substrate to increase the overspray of the cathode.

In one embodiment of the method of manufacturing the display panel, the step of depositing the cathode covering the organic electronic functional layer and another part of the bonding pad pattern further includes widening a distance between a mask and the substrate to increase the overspray of the cathode.

Another embodiment of the disclosure further provides a machine of manufacturing a display panel according to the method of manufacturing the display panel aforementioned, including:
a buffer chamber configured to transmit and receive the substrate;
a mask aligning chamber configured to cover the mask over a surface of the substrate and align the mask with the substrate;
an evaporation/sputtering chamber configured to perform the step of depositing the organic electronic functional layer covering the light emitting layer and the part of the bonding pad pattern and the step of depositing the cathode covering the organic electronic functional layer and another part of the bonding pad pattern on the substrate; and
a mask separation chamber configured to remove the mask from the substrate.

In one embodiment of the machine of manufacturing the display panel, the machine of manufacturing the display panel further includes a mask returning chamber and another two buffer chambers disposed between the mask returning chamber and the mask aligning chamber and between the mask returning chamber and the mask separation chamber respectively, and the two buffer chamber cooperating with the mask returning chamber are configured to select and transmit a suitable mask to the mask aligning chamber to aligning the mask.

In one embodiment of the disclosure, the machine of manufacturing the display panel further includes still another buffer chamber disposed beside the mask aligning chamber to receive and accommodate the substrate provided with an inkjet printing hole injection layer, an inkjet printing hole transport layer, and an inkjet printing light emitting layer from outside of the machine of manufacturing the display panel and to transmit the substrate to the mask aligning chamber to align with the mask.

In comparison with prior art, the disclosure provides the display panel, the method of manufacturing the display panel, and the machine of manufacturing the display panel include the overspray of the organic electronic functional layer covers the part of the bonding pad pattern and the overspray of the cathode covers the overspray of the organic electronic functional layer and another part of the bonding pad pattern to solve the technical issues of simplification of the display panel manufacturing process and overlap of the CAT film layer and the metal wiring simultaneously.

### BRIEF DESCRIPTION OF DRAWINGS

FIG. 1 is a schematic view of a structure of a display panel of an embodiment of the present disclosure.

FIG. 2 is a schematic flowchart of a method of manufacturing a display panel of an embodiment of the present disclosure.

FIG. 3 is a schematic view of a structure of a display panel in a process of manufacturing a display panel of an embodiment of the present disclosure.

FIG. 4 is a schematic partial enlarged view of FIG. 3.

FIG. 5 is a schematic view of an arrangement of evaporation of an embodiment of the present disclosure.

FIG. 6 is a schematic view of an arrangement of sputtering of an embodiment of the present disclosure.

FIG. 7 is a schematic cross-sectional view of an arrangement of a mask and a substrate of an embodiment of the present disclosure.

FIG. 8 is a schematic view of an arrangement of a machine of manufacturing a display panel of an embodiment of the present disclosure.

FIG. 9 is a schematic view of curves of deposition film thickness vs. horizontal distance for evaporation and sputtering of an embodiment of the present disclosure.

FIG. 10 is a schematic view of a structure of a substrate of an embodiment of the present disclosure.

FIG. 11 is a schematic view of a structure of a display panel in a process of manufacturing a display panel of an embodiment of the present disclosure.

FIG. 12 is a schematic view of a structure of a display panel in a process of manufacturing a display panel of an embodiment of the present disclosure.

### DETAILED DESCRIPTION

The specific structure and functional details disclosed herein are only representative and are used for the purpose of describing exemplary embodiments of the present application. However, this application can be implemented in many alternative forms, and should not be interpreted as being limited only to the embodiments set forth herein.

In the description of this application, it should be understood that the terms “center”, “lateral”, “upper”, “lower”, “left”, “right”, “vertical”, “horizontal”, “top”, The orientation or positional relationship indicated by “bottom”, “inner”, “outer”, etc. is based on the orientation or positional relationship shown in the drawings, and is only for the convenience of describing the application and simplifying the description, and does not indicate or imply the pointed device Or the element must have a specific orientation, be constructed and operated in a specific orientation, and therefore cannot be understood as a limitation of the present application. In addition, the terms “first” and “second” are only used for descriptive purposes and cannot be understood as indicating or implying relative importance or implicitly indicating the number of indicated technical features. Therefore, the features defined with “first” and “second” may explicitly or implicitly include one or more of these features. In the description of this application, unless otherwise specified, “plurality” means two or more. In addition, the term “including” and any variations thereof is intended to cover non-exclusive inclusion.

In the description of this application, it should be noted that the terms “installation”, “connection”, and “connection” should be understood in a broad sense unless otherwise clearly specified and limited. For example, it can be a support connection or a detachable connection. Connected or integrally connected; it can be a mechanical connection or an electrical connection; it can be directly connected or indirectly connected through an intermediate medium, and it can be the internal communication between two components. For those of ordinary skill in the art, the specific meanings of the above-mentioned terms in this application can be understood under specific circumstances.

The terminology used here is only for describing specific embodiments and is not intended to limit the exemplary embodiments. Unless the context clearly dictates otherwise, the singular forms “a” and “one” used herein are also intended to include the plural. It should also be understood that the terms “including” and/or “comprising” used herein specify the existence of the stated features, integers, steps, operations, units and/or components, and do not exclude the existence or addition of one or more other features, integers, steps, operations, units, components, and/or combinations thereof.

The application will be further described below in conjunction with the drawings and embodiments.

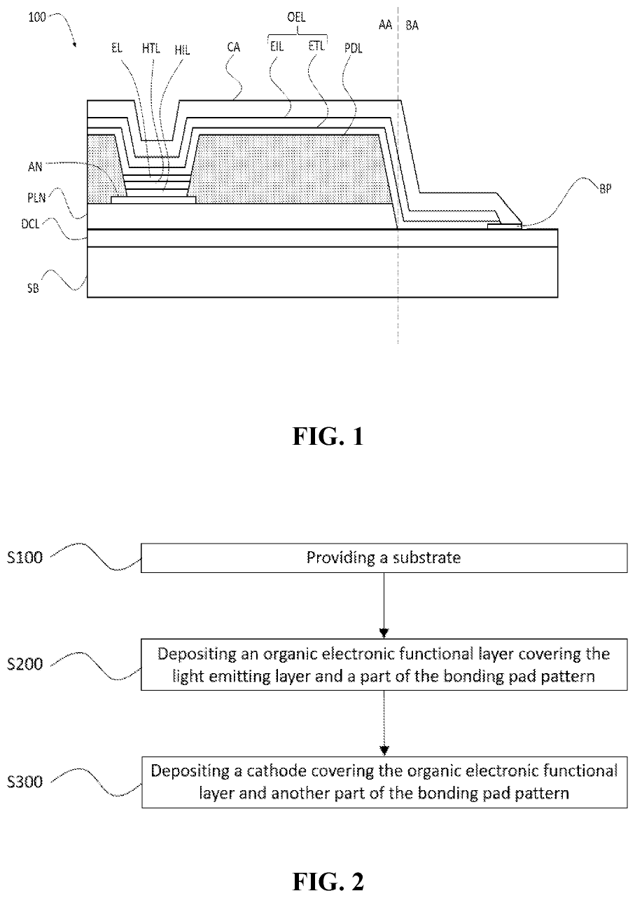

Referring to FIG. 1, FIG. 1 is a schematic view of a structure of a display panel of an embodiment of the present disclosure. One embodiment of the disclosure provides a display panel 100, dividing to a display region AA and a bonding region BA and including: a substrate SB; a bonding pad pattern BP disposed on the substrate SB within the bonding region BA; an anode AN disposed on the substrate SB within the display region AA; a light emitting layer EL disposed on the anode AN; an organic electronic functional layer OEL covering the light emitting layer EL; and a cathode CA covering the organic electronic functional layer OEL, wherein the organic electronic functional layer OEL further covers a part of the bonding pad pattern BP, and the cathode CA further covers another part of the bonding pad pattern BP.

In detail, in some embodiment of the display panel 100 of the disclosure, the bonding region BA is for example a circuit region outside the display region AA.

In one embodiment of the display panel, the organic electronic functional layer OEL includes an electron transport layer ETL and an electron injection layer EIL stacked thereon.

In detail, in some embodiment of the disclosure, the display panel 100 further includes a driving circuit layer DCL disposed on the substrate SB, a planarization layer PLN covering the driving circuit layer DCL, the anode AN disposed on the planarization layer PLN, a pixel definition layer PDL disposed on the planarization layer PLN and covering part of the anode AN, wherein the pixel definition layer PDL is provided with an opening, a hole injection layer HIL and a hole transport layer HTL are disposed in the opening in a stack, and the light emitting layer EL is disposed on the hole transport layer HTL. An electron transport layer ETL covers the light emitting layer EL, the pixel definition layer PDL, a part of the driving circuit layer DCL and contacts with the bonding pad pattern BP. An electron injection layer EIL covers the electron transport layer ETL, contacts the bonding pad pattern BP, and covers a part of the bonding pad pattern BP. The cathode CA covers the electron injection layer EIL and another part of the bonding pad pattern BP.

In detail, the driving circuit layer DCL includes driving transistors and circuit traces. The traces are connected to the anode AN, the bonding pad pattern BP, etc. through holes. The driving circuit layer DCL also includes a passivation layer to provide proper insulation for the traces, for example, insulation from the electron transport layer ETL. The driving circuit layer DCL is not the focus of this case, so its details are not shown.

In detail, please refer to FIG. 9, FIG. 9 is a schematic diagram of a curve of the deposition film thickness versus the horizontal distance of the evaporation method and the sputtering method provided by the embodiment of the present application. In detail, an edge of an opening of the mask MK is approximately between the horizontal distance from 0 to 0.5 in the figure. During the deposition process, because the mask MK and the substrate SB cannot be completely attached, the deposits slightly exceed the opening position of the mask MK and deposit to the position where the mask MK is covering. This area is called an overspray area. In detail, a sputtering direction of particles in sputtering SPT method is random, while the particles in evaporation EV method are limited by an evaporation angle. Therefore, an overspray SOA formed by sputtering SPT will be larger than an overspray EOA formed by evaporation EV.

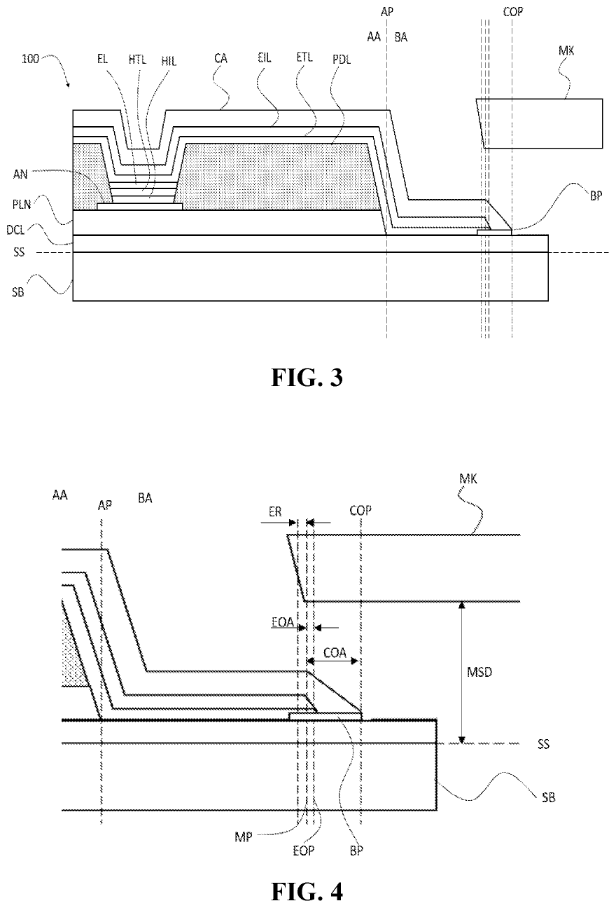

In detail, please refer to FIG. 3 and FIG. 4. FIG. 3 is a schematic view of a structure of a display panel in a process of manufacturing a display panel of an embodiment of the present disclosure. FIG. 4 is a schematic partial enlarged view of FIG. 3. In the embodiment of the disclosure, the organic electronic functional layer OEL further covers a part of the bonding pad pattern BP. Method to provide a structure of the organic electronic functional layer OEL further covering the part of the bonding pad pattern BP and the cathode CA further covering another part of the bonding pad pattern BP includes an overspray EOA of the organic electronic functional layer OEL covering the part of the bonding pad pattern BP and an overspray COA of the cathode CA covering the overspray EOA of the organic electronic functional layer OEL and another part of the bonding pad pattern BP.

In detail, because the cathode CA directly contacts the other part of the bonding pad pattern BP through the overspray COA, there is no overspray EOA of the electronic function layer OEL disposed between the overspray COA of the cathode CA and another part of the bonding pad pattern BP. It can therefore provide a good electrical connection between the cathode CA and the bonding pad pattern BP and solve the issue of poor connection between the cathode and the bonding pad pattern in the prior art.

Please refer to FIG. 2, FIG. 2 is a schematic flowchart of a method of manufacturing a display panel of an embodiment of the present disclosure. Another embodiment of the disclosure further provides a method of manufacturing a display panel, including steps of:

S100: providing a substrate, wherein the substrate is dividing to a display region and a bonding region, and the substrate includes a bonding pad pattern disposed within the bonding region and light emitting layer disposed within the display region; S200: depositing an organic electronic functional layer covering the light emitting layer and a part of the bonding pad pattern; and S300: depositing a cathode covering the organic electronic functional layer and another part of the bonding pad pattern.

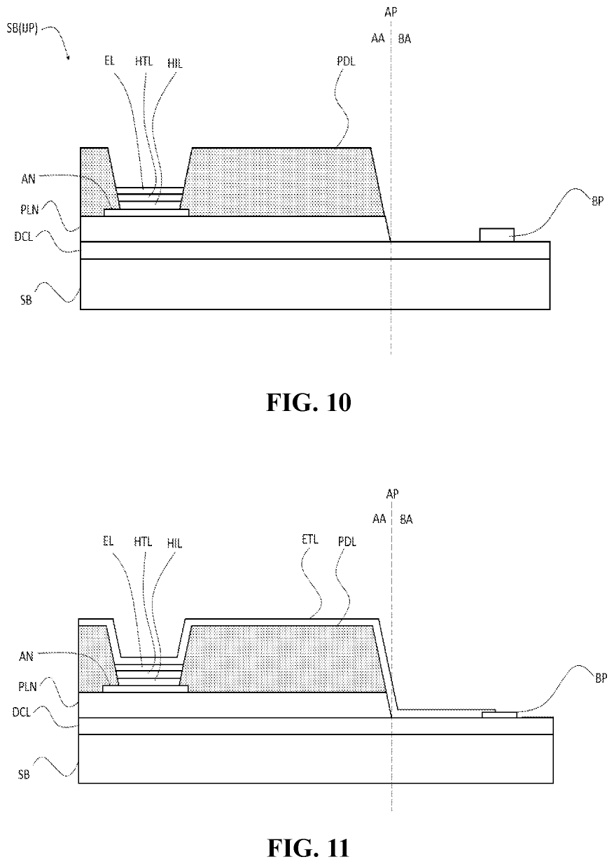

In detail, please refer to FIG. 10, FIG. 10 is a schematic view of a structure of a substrate of an embodiment of the present disclosure. In some embodiment of the method of manufacturing the display panel, the substrate SB(IJP) provided in step S100 includes a driving circuit layer DCL disposed on the substrate SB, a planarization layer PLN covering the driving circuit layer DCL, the anode AN disposed on the planarization layer PLN, a pixel definition layer PDL disposed on the planarization layer PLN and covering part of the anode AN, wherein the pixel definition layer PDL is provided with an opening, a hole injection layer HIL and a hole transport layer HTL are disposed in the opening in a stack, and the light emitting layer EL is disposed on the hole transport layer HTL.

In detail, the hole injection layer HIL, the hole transport layer HTL, and the light emitting layer EL are made by inkjet printing (UP) method.

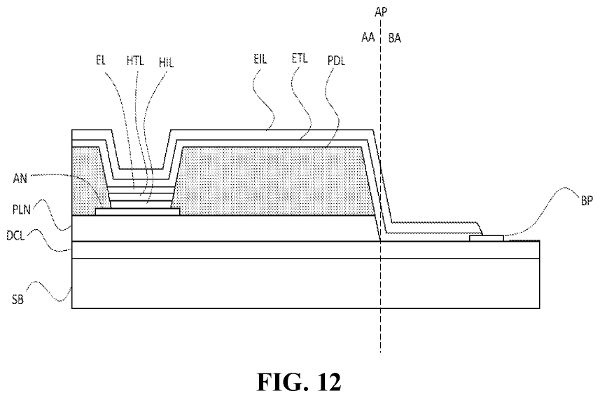

In detail, please refer to FIG. 11 and FIG. 12, FIG. 11 and FIG. 12 are schematic views of a structure of a display panel in a process of manufacturing a display panel of an embodiment of the present disclosure. In some embodiment of the method of manufacturing the display panel, the step S200: depositing the organic electronic functional layer covering the light emitting layer and the part of the bonding pad pattern includes: depositing an electron transport layer ETL covering the light emitting layer EL, the pixel definition layer PDL, a part of the driving circuit layer DCL and contacting with the bonding pad pattern BP, and depositing an electron injection layer EIL covering the electron transport layer ETL, contacting the bonding pad pattern BP, and covering a part of the bonding pad pattern BP.

In detail, please refer to FIG. 1. In some embodiment of the method of manufacturing the display panel, the step S300: depositing the cathode covering the organic electronic functional layer and another part of the bonding pad pattern use a same mask includes: depositing the cathode CA covering the electron injection layer EIL and another part of the bonding pad pattern BP.

Please refer to FIG. 2, FIG. 3, and FIG. 4. FIG. 2 is a schematic flowchart of a method of manufacturing a display panel of an embodiment of the present disclosure. In some embodiment of the method of manufacturing the display panel, the step S200: depositing the organic electronic functional layer covering the light emitting layer and the part of the bonding pad pattern and the step S300: depositing the cathode covering the organic electronic functional layer and another part of the bonding pad pattern use a same mask MK.

In detail, the method of manufacturing the display panel provided by the embodiment of the present application provides the overspray EOA of the organic electronic functional layer OEL to cover the part of the bonding pad pattern BP, and the overspray COA of the cathode CA to cover the overspray EOA of the organic electronic functional layer OEL and another part of the bonding pad pattern BP. Therefore, the cathode CA can directly contact another part of the pad pattern BP through the overspray COA, and the organic electronic functional layer OEL is not disposed between the overspray COA of the cathode CA and another part of the bonding pad pattern BP. A same mask MK can be used to perform the step S200: depositing the organic electronic functional layer covering the light emitting layer and the part of the bonding pad pattern and the step S300: depositing the cathode covering the organic electronic functional layer and another part of the bonding pad pattern. It does not need to use two masks with different opening sizes and can provide a good electrical connection between the cathode CA and the bonding pad pattern BP and at the same time solves the issue of poor connection between the cathode and the bonding pad pattern in the prior art.

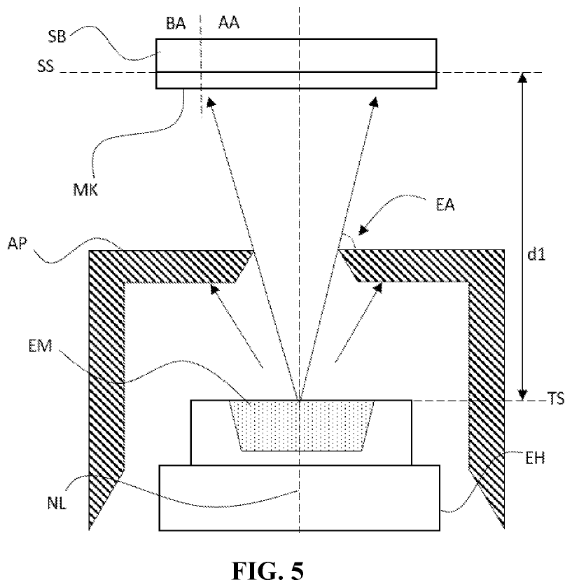

Please refer to FIG. 2, FIG. 4, and FIG. 5. FIG. 5 is a schematic view of an arrangement of evaporation of an embodiment of the present disclosure. In some embodiment of the method of manufacturing the display panel, the step S200: depositing the organic electronic functional layer covering the light emitting layer and the part of the bonding pad pattern includes depositing the organic electronic functional layer OEL by evaporation, wherein an overspray EOA of the organic electronic functional layer OEL covers the part of the bonding pad pattern BP.

Please refer to FIG. 2, FIG. 4, and FIG. 5. In some embodiment of the method of manufacturing the display panel, the step S200: depositing the organic electronic functional layer covering the light emitting layer and the part of the bonding pad pattern further includes reducing a distance d1 between an evaporation source EM and the substrate SB to reduce the overspray EOA of the organic electronic functional layer EOL.

In detail, the distance from the intersection of the center of the surface SS of the substrate SB and the normal line NL of the surface TS of the evaporation source EM to the surface TS of the evaporation source EM is d1. The evaporation source EM is arranged on the heating base EH to heat and evaporate the evaporation source EM to coat the surface of the substrate SB through the mask MK. The longer the distance d1 is, the more difficult it is to control the traveling direction of the vapor-deposited particles, and the longer the length of the overspray EOA is.

Please refer to FIG. 2, FIG. 4, and FIG. 5. In some embodiment of the method of manufacturing the display panel, the step S200: depositing the organic electronic functional layer covering the light emitting layer and the part of the bonding pad pattern further includes changing an evaporation angle EA of an evaporation source EM to reduce the overspray EOA of the organic electronic functional layer OEL.

In detail, angle plates AP are provided on both sides of the evaporation source EM to adjust the evaporation angle EA. The evaporation source EM is arranged on the heating base EH to heat and evaporate the evaporation source EM and is limited by the angle plate AP and is coated on the surface of the substrate SB through the mask MK. When the angle plate AP is adjusted to make the evaporation angle EA larger, the length of the overspray EOA is shorter.

In detail, if the deposition of the cathode CA and the deposition of the organic electronic functional layer OEL both use an evaporation method, it can be set to reduce the evaporation angle EA when the cathode CA is deposited, so that the length of the overspray EOA of cathode CA is increased. When depositing the organic electronic functional layer OEL, the evaporation angle EA is increased to reduce the length of the overspray EOA of the organic electronic functional layer OEL.

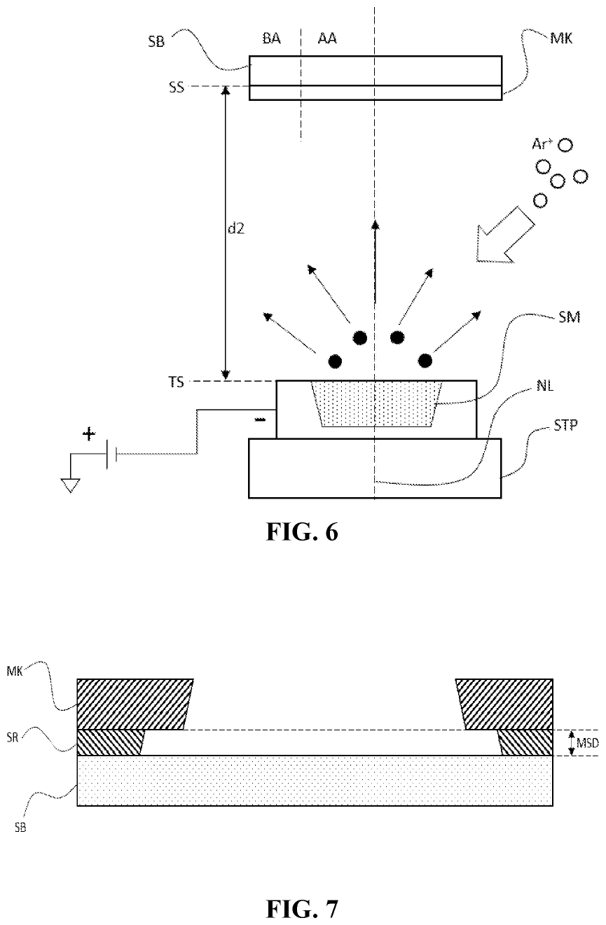

Please refer to FIG. 2, FIG. 4, and FIG. 6. FIG. 6 is a schematic view of an arrangement of sputtering of an embodiment of the present disclosure. In one embodiment of the method of manufacturing the display panel, the step S300: depositing the cathode covering the organic electronic functional layer and another part of the bonding pad pattern includes depositing the cathode by evaporation or sputtering, wherein an overspray COA of the cathode CA covers the overspray EOA of the organic electronic functional layer OEL and another part of the bonding pad pattern BP.

In detail, taking the sputtering method to deposit the cathode CA as an example, the sputtering target SM is set on the sputtering platform STP and connected to a negative charge, and positively charged argon ions are introduced to bombard the sputtering target SM to make the sputtering particles scattered and coated on the surface of the substrate SB through the mask MK. The sputtering direction of the particles produced by the sputtering method is relatively random. Therefore, compared with the evaporation method, the sputtering method produces a larger overspray.

Please refer to FIG. 2, FIG. 4, and FIG. 6. In one embodiment of the method of manufacturing the display panel, the step S300: depositing the cathode covering the organic electronic functional layer and another part of the bonding pad pattern further includes widening a distance d2 between an evaporation source EM or sputtering target SM and the substrate SB to increase the overspray of the cathode.

In detail, taking the sputtering method to deposit the cathode CA as an example, the distance between the surface TS of the sputtering target SM and the surface SS of the substrate SB is d2. Similar to the evaporation method, the longer the distance d2, the more chaotic the traveling direction of the sputtered particles, and the longer the length of the overspray COA. Conversely, reducing the distance d2 can reduce the length of the overspray COA of the cathode.

Please refer to FIG. 2, FIG. 4, and FIG. 7. FIG. 7 is a schematic cross-sectional view of an arrangement of a mask and a substrate of an embodiment of the present disclosure. In one embodiment of the method of manufacturing the display panel, the step S300: depositing the cathode covering the organic electronic functional layer and another part of the bonding pad pattern further includes widening a distance MSD between a mask MK and the substrate SB to increase the overspray COA of the cathode CA.

The application does not limit the specific way of increasing the distance MSD between the mask MK and the substrate SB.

In detail, in the method of manufacturing the display panel of some embodiments of the present application, a spacer SR is arranged between the mask MK and the substrate SB to increase the distance MSD. The spacer SR is, for example, a protrusion formed on the mask MK by etching, stamping, welding and casting, or a spacer provided between the mask MK and the substrate SB. The present application does not limit the method of manufacturing the protrusion or the gasket, nor does it limit the shape of the protrusion or the gasket.

In detail, increasing the overspray COA of the cathode CA and/or shrinking the overspray EOA of the organic electronic functional layer OEL can increase contact area of the overspray COA of the cathode CA and the bonding pad pattern BP, therefore provide a good electrical connection between the cathode CA and the bonding pad pattern BP, and solve the issue of poor connection between the cathode and the bonding pad pattern in the prior art.

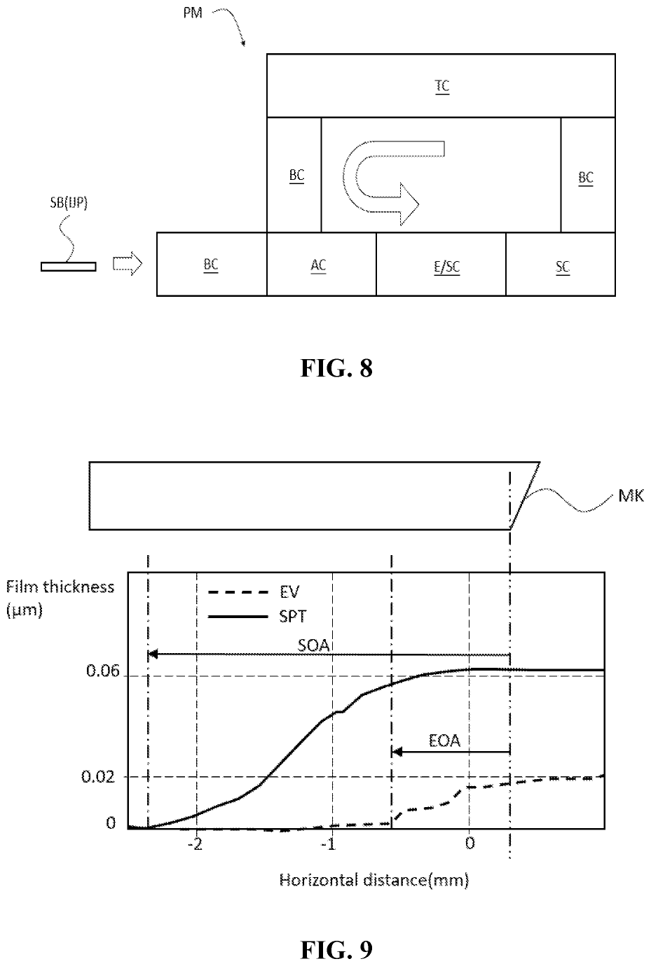

Please refer to FIG. 2 and FIG. 8. FIG. 8 is a schematic view of an arrangement of a machine of manufacturing a display panel of an embodiment of the present disclosure. Another embodiment of the disclosure further provides a machine PM of manufacturing a display panel according to any of the method of manufacturing the display panel aforementioned, including: a buffer chamber BC configured to transmit and receive the substrate SB(IJP); a mask aligning chamber AC configured to cover the mask MK over a surface of the substrate SB(IJP) and align the mask MK with the substrate SB(IJP); an evaporation/sputtering chamber E/SC configured to perform the step S200: depositing the organic electronic functional layer covering the light emitting layer and the part of the bonding pad pattern and the step S300: depositing the cathode covering the organic electronic functional layer and another part of the bonding pad pattern on the substrate; and a mask separation chamber SC configured to remove the mask MK from the substrate SB(IJP).

In detail, the buffer chamber BC receives and accommodates the substrate SB(IJP) provided with an inkjet printing hole injection layer HIL, an inkjet printing hole transport layer HTL, and an inkjet printing light emitting layer EL and to transmit the substrate SB(IJP) to the mask aligning chamber AC to align with the mask MK.

In detail, the machine PM of manufacturing the display panel further includes a mask returning chamber TC and another two buffer chambers BC disposed between the mask returning chamber TC and the mask aligning chamber AC and between the mask returning chamber TC and the mask separation chamber SC respectively, and the two buffer chamber BC cooperating with the mask returning chamber TC are configured to select and transmit a suitable mask MK to the mask aligning chamber AC to aligning the mask MK.

In detail, the method of manufacturing the display panel provided by the embodiment of the present application provides the overspray EOA of the organic electronic functional layer OEL to cover the part of the bonding pad pattern BP, and the overspray COA of the cathode CA to cover the overspray EOA of the organic electronic functional layer OEL and another part of the bonding pad pattern BP. Therefore, the cathode CA can directly contact another part of the pad pattern BP through the overspray COA, and the organic electronic functional layer OEL is not disposed between the overspray COA of the cathode CA and another part of the bonding pad pattern BP. A same mask MK can be used to perform the step S200: depositing the organic electronic functional layer covering the light emitting layer and the part of the bonding pad pattern and the step S300: depositing the cathode covering the organic electronic functional layer and another part of the bonding pad pattern in the evaporation/sputtering chamber E/SC. It does not need to use two masks with different opening sizes, therefore, there is no need for additional production line platforms to layout 2 cyclic processes to simplify the display panel manufacturing process and reduce costs and provide a good electrical connection between the cathode CA and the bonding pad pattern BP and at the same time solves the issue of poor connection between the cathode and the bonding pad pattern in the prior art.

In comparison with prior art, the disclosure provides the display panel, the method of manufacturing the display panel, and the machine of manufacturing the display panel include the overspray of the organic electronic functional layer covers the part of the bonding pad pattern and the overspray of the cathode covers the overspray of the organic electronic functional layer and another part of the bonding pad pattern to solve the technical issues of simplification of the display panel manufacturing process and overlap of the CAT film layer and the metal wiring simultaneously.

The display panel, the method of manufacturing the display panel, and the machine of manufacturing the display panel provided by the embodiments of the present application are described in detail above.

For the specific implementation of the above operations, please refer to the previous embodiments, which will not be repeated here.

In summary, although the application has been disclosed as above in preferred embodiments, the above-mentioned preferred embodiments are not intended to limit the application. Those of ordinary skill in the art can make various decisions without departing from the spirit and scope of the application. Such changes and modifications, so the protection scope of this application is subject to the scope defined by the claims.

What is claimed is:

1. A display panel, dividing to a display region and a bonding region and comprising:
a substrate;
a bonding pad pattern disposed on the substrate within the bonding region;
an anode disposed on the substrate within the display region;
a light emitting layer disposed on the anode;
an organic electronic functional layer covering the light emitting layer; and
a cathode covering the organic electronic functional layer, wherein the organic electronic functional layer further covers a part of the bonding pad pattern, and the cathode further covers another part of the bonding pad pattern.

2. The display panel according to claim 1, wherein the organic electronic functional layer comprises an electron transport layer and an electron injection layer stacked thereon.

3. The display panel according to claim 1, wherein the organic electronic functional layer extends from the display region to the bonding region, and the cathode extends from the display region to the bonding region.

4. The display panel according to claim 1, further comprising a driving circuit layer disposed on the substrate, a planarization layer covering the driving circuit layer, the anode disposed on the planarization layer, a pixel definition layer disposed on the planarization layer and covering part of the anode, wherein the pixel definition layer is provided with an opening, a hole injection layer and a hole transport layer are disposed in the opening in a stack, and the light emitting layer is disposed on the hole transport layer.

5. The display panel according to claim 4, wherein the organic electronic functional layer comprises an electron transport layer covering the light emitting layer, the pixel definition layer, a part of the driving circuit layer and contacting with the bonding pad pattern and an electron injection layer covering the electron transport layer, contacting the bonding pad pattern, and covering a part of the bonding pad pattern, wherein the cathode covers the electron injection layer and another part of the bonding pad pattern.

6. A method of manufacturing a display panel, comprising steps of:
providing a substrate, wherein the substrate is dividing to a display region and a bonding region, and the substrate comprises a bonding pad pattern disposed within the bonding region and light emitting layer disposed within the display region;
depositing an organic electronic functional layer covering the light emitting layer and a part of the bonding pad pattern; and
depositing a cathode covering the organic electronic functional layer and another part of the bonding pad pattern.

7. The method of manufacturing the display panel according to claim 6, wherein the step of depositing the organic electronic functional layer covering the light emitting layer and the part of the bonding pad pattern and the step of depositing the cathode covering the organic electronic functional layer and another part of the bonding pad pattern use a same mask.

8. The method of manufacturing the display panel according to claim 6, wherein the step of depositing the organic electronic functional layer covering the light emitting layer and the part of the bonding pad pattern comprises depositing the organic electronic functional layer by evaporation, wherein an overspray of the organic electronic functional layer covers the part of the bonding pad pattern.

9. The method of manufacturing the display panel according to claim 8, wherein the step of depositing the organic electronic functional layer covering the light emitting layer and the part of the bonding pad pattern further comprises widening a distance between an evaporation source and the substrate to reduce the overspray of the organic electronic functional layer.

10. The method of manufacturing the display panel according to claim 8, wherein the step of depositing the organic electronic functional layer covering the light emitting layer and the part of the bonding pad pattern further comprises changing an evaporation angle of an evaporation source to reduce the overspray of the organic electronic functional layer.

11. The method of manufacturing the display panel according to claim 6, wherein the step of depositing the cathode covering the organic electronic functional layer and another part of the bonding pad pattern comprises depositing the cathode by evaporation, wherein an overspray of the cathode covers the overspray of the organic electronic functional layer and another part of the bonding pad pattern.

12. The method of manufacturing the display panel according to claim 11, wherein the step of depositing the cathode covering the organic electronic functional layer and another part of the bonding pad pattern further comprises changing an evaporation angle of an evaporation source to increase the overspray of the cathode.

13. The method of manufacturing the display panel according to claim 11, wherein the step of depositing the cathode covering the organic electronic functional layer and another part of the bonding pad pattern further comprises widening a distance between an evaporation source and the substrate to increase the overspray of the cathode.

14. The method of manufacturing the display panel according to claim 11, wherein the step of depositing the cathode covering the organic electronic functional layer and another part of the bonding pad pattern further comprises widening a distance between a mask and the substrate to increase the overspray of the cathode.

15. The method of manufacturing the display panel according to claim 6, wherein the step of depositing the cathode covering the organic electronic functional layer and another part of the bonding pad pattern comprises depositing the cathode by sputtering, wherein an overspray of the cathode covers the overspray of the organic electronic functional layer and another part of the bonding pad pattern.

16. The method of manufacturing the display panel according to claim 15, wherein the step of depositing the cathode covering the organic electronic functional layer and another part of the bonding pad pattern further comprises widening a distance between a sputtering target and the substrate to increase the overspray of the cathode.

17. The method of manufacturing the display panel according to claim 15, wherein the step of depositing the cathode covering the organic electronic functional layer and another part of the bonding pad pattern further comprises widening a distance between a mask and the substrate to increase the overspray of the cathode.

18. A machine of manufacturing a display panel according to the method of manufacturing the display panel of claim 6, comprising:
a buffer chamber configured to transmit and receive the substrate;
a mask aligning chamber configured to cover the mask over a surface of the substrate and align the mask with the substrate;
an evaporation/sputtering chamber configured to perform the step of depositing the organic electronic functional layer covering the light emitting layer and the part of the bonding pad pattern and the step of depositing the cathode covering the organic electronic functional layer and another part of the bonding pad pattern on the substrate; and
a mask separation chamber configured to remove the mask from the substrate.

19. The machine of manufacturing the display panel according to claim 18, wherein the machine of manufacturing the display panel further comprises a mask returning chamber and another two buffer chambers disposed between the mask returning chamber and the mask aligning chamber and between the mask returning chamber and the mask separation chamber respectively, and the two buffer chamber cooperating with the mask returning chamber are configured to select and transmit a suitable mask to the mask aligning chamber to aligning the mask.

20. The machine of manufacturing the display panel according to claim 19, further comprising still another buffer chamber disposed beside the mask aligning chamber to receive and accommodate the substrate provided with an inkjet printing hole injection layer, an inkjet printing hole transport layer, and an inkjet printing light emitting layer from outside of the machine of manufacturing the display panel and to transmit the substrate to the mask aligning chamber to align with the mask.
